(19) United States
(12) Patent Application Publication
(10) Pub. No.: US 2012/0261362 A1
(43) Pub. Date: Oct. 18, 2012

(54) DISPLAY SUPPORT COLUMN

(76) Inventors: Joseph Skull, Fridley, MN (US); Robert Hagen, Minneapolis, MN (US)

(21) Appl. No.: 13/445,677

(22) Filed: Apr. 12, 2012

Related U.S. Application Data
(60) Provisional application No. 61/475,646, filed on Apr. 14, 2011.

(51) Int. Cl. H05K 7/18; H05K 7/00

(52) U.S. Cl. 211/26; 248/205.1; 248/225.11

(57) ABSTRACT

A flat panel display mount attachable to a piece of furniture that can safely accommodate the increased loading from large flat panel display devices.

### RELATED APPLICATIONS

This application claims of the benefit of U.S. Provisional Patent Application No. 61/475,646 entitled DISPLAY SUPPORT COLUMN and filed Apr. 14, 2011, said application being hereby fully incorporated herein by reference.

### FIELD OF THE INVENTION

The present invention relates to mounts for flat panel televisions and monitors, and more specifically, to mounts for attaching a flat panel television to furniture.

### BACKGROUND OF THE INVENTION

Prior mounts for attaching flat panel televisions to furniture have generally included desk clamp and arm assemblies, as well as wall type mounts that attach to the back plane of taller furniture pieces. These mounts are generally unsuitable, however, for larger flat panel displays, such as for those 30 inches and larger, due to the increased structural integrity needed for the greater weight of the display.

As a result, there is a need in the industry for a flat panel display mount attachable to a piece of furniture that can safely accommodate the increased loading from large flat panel display devices.

### SUMMARY OF THE INVENTION

The present invention addresses the need in the industry for a flat panel display mount attachable to a piece of furniture that can safely accommodate the increased loading from large flat panel display devices.

According to an embodiment, a mounting device for attaching an electronic display to an article of furniture includes a body portion with a pair of spaced-apart elongate vertical members, the body portion presenting a top end and a bottom end and defining structure proximate the bottom end for attaching the body portion to the article of furniture, a display mount adapted to receive the electronic display thereon coupled to the body portion proximate the top end, and a selectively removable accessory attachment bracket frictionally engaged between the vertical members of the body portion. In embodiments, the display mount may include a tilt-head assembly. The structure for attaching the body portion may comprise a slot angled with respect to the horizontal. The vertical members may have a square cross-section.

In embodiments, the accessory attachment bracket may comprise an elongate member presenting four corners, two of the corners being rounded, and may define structure such as a slot for receiving an accessory mounting attachment. The accessory mounting attachment may comprise a hook structure received in the slot.

According to another embodiment, an article of furniture includes a shelf structure presenting at least one horizontally oriented shelf surface, and a mounting device for attaching an electronic display to the shelf structure. The mounting device includes a body portion with a pair of spaced-apart elongate vertical members, the body portion presenting a top end and a bottom end and defining a pair of angled slots proximate the bottom end for receiving fasteners to attach the body portion to the shelf structure, and a display mount coupled to the body portion proximate the top end, the display mount adapted to receive the electronic display thereon. In further embodiments, the article of furniture may include a selectively removable accessory attachment bracket frictionally engaged between the vertical members of the body portion. The accessory attachment bracket may be an elongate member presenting four corners, two of the corners being rounded, and may define structure for receiving an accessory mounting attachment.

In another embodiment, a mounting device for attaching an electronic display to an article of furniture includes a body portion including a pair of spaced-apart elongate vertical members, the body portion presenting a top end and a bottom end and defining a pair of angled slots proximate the bottom end for attaching the body portion to the article of furniture, and a display mount coupled to the body portion proximate the top end, the display mount adapted to receive the electronic display thereon. A selectively removable accessory attachment bracket may be frictionally engaged between the vertical members of the body portion.

### BRIEF DESCRIPTION OF THE FIGURES

The invention may be more completely understood in consideration of the following detailed description of various embodiments of the invention in connection with the accompanying drawings, in which:

FIG. 1 is a front perspective view of a mount according to an embodiment of the present invention attached to a shelf structure and supporting a flat panel television;

FIG. 2 is a front perspective view of a column display mount according to an embodiment of the invention;

FIG. 3 is a rear perspective view of the column display mount of FIG. 2;

FIG. 4 is a front perspective view of the top portion of the column display mount of FIG. 2 with the tilt display mount portion omitted for clarity;

FIG. 5 is a front perspective view of the furniture attachment portion of the column display mount of FIG. 2;

FIG. 6 is a rear perspective view of the column display mount of FIG. 2 with removable accessory attachment brackets installed;

FIG. 7 is a front view of one of the removable accessory attachment brackets depicted in FIG. 6;

FIG. 8 is a front view of another of the removable accessory attachment brackets depicted in FIG. 6;

FIG. 9 is a rear view of the removable accessory attachment bracket of FIG. 7;

FIG. 10 is a rear view of the removable accessory attachment bracket of FIG. 8;

FIG. 11 is an exploded view of the removable accessory attachment bracket of FIG. 7;

FIG. 12 is an exploded view of the removable accessory attachment bracket of FIG. 8;

FIG. 13 is a fragmentary rear perspective view of the column display mount of FIG. 2 with a removable accessory attachment bracket in an initial stage of installation;

FIG. 14 is a fragmentary rear perspective view of the column display mount of FIG. 2 with a removable accessory attachment bracket in a further stage of installation; and

FIG. 15 is a fragmentary rear perspective view of the column display mount of FIG. 2 with a removable accessory attachment bracket in a still further stage of installation.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives.

### DETAILED DESCRIPTION OF THE PREFERRED EMBODIMENTS

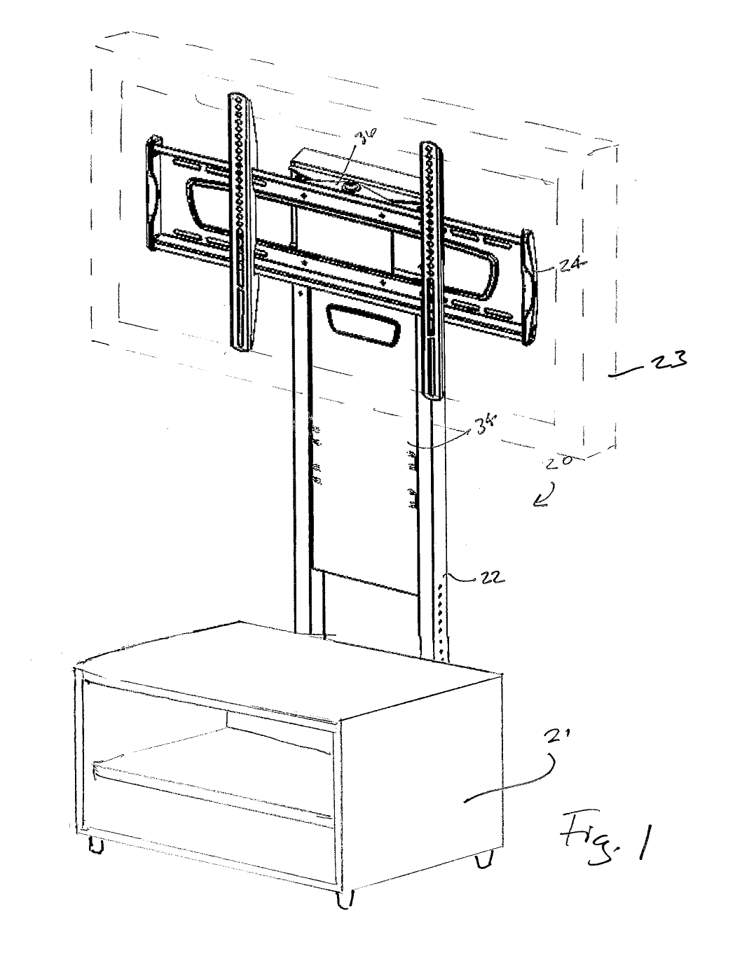

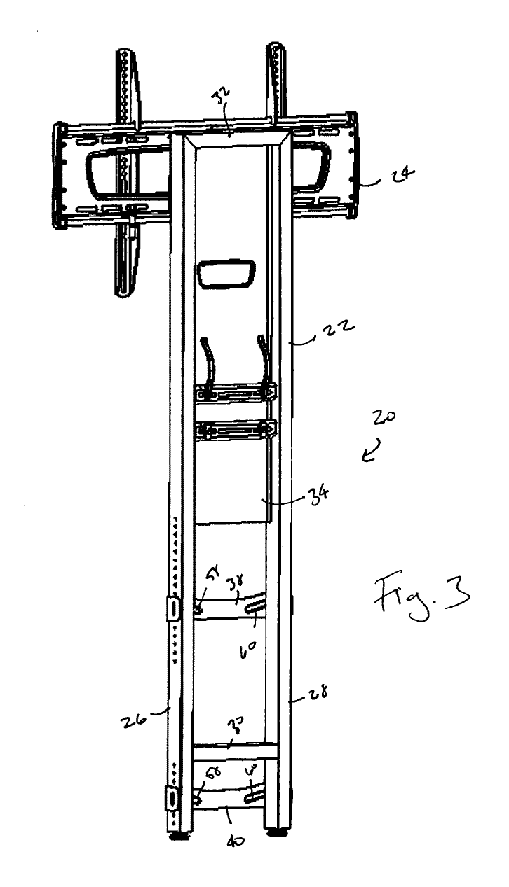

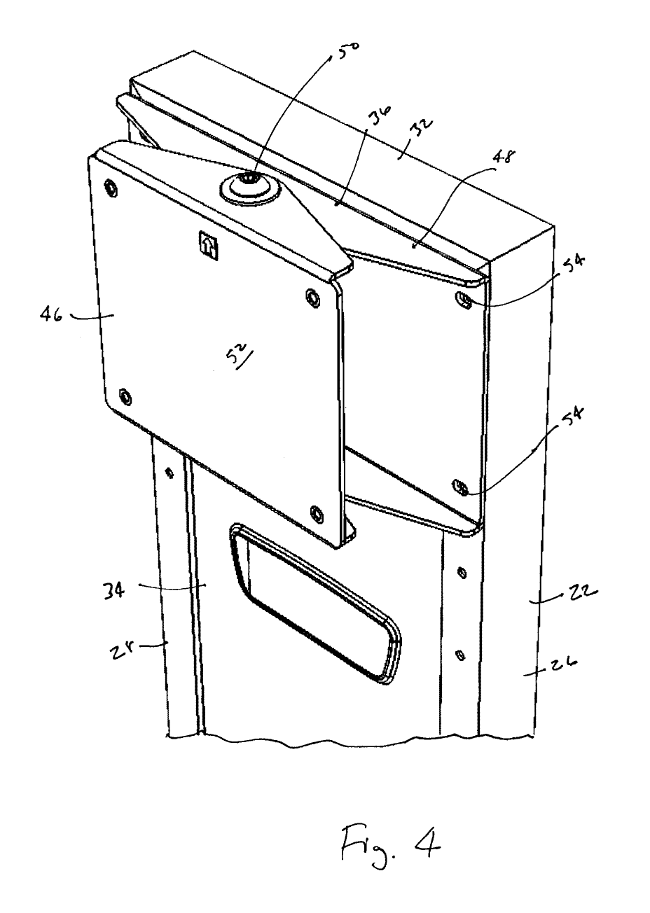

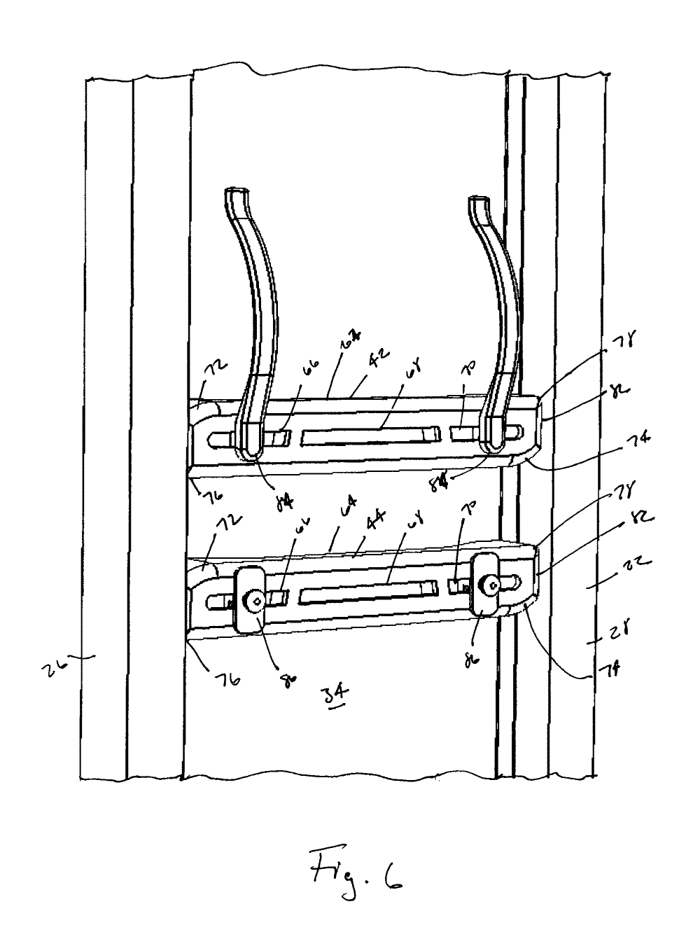

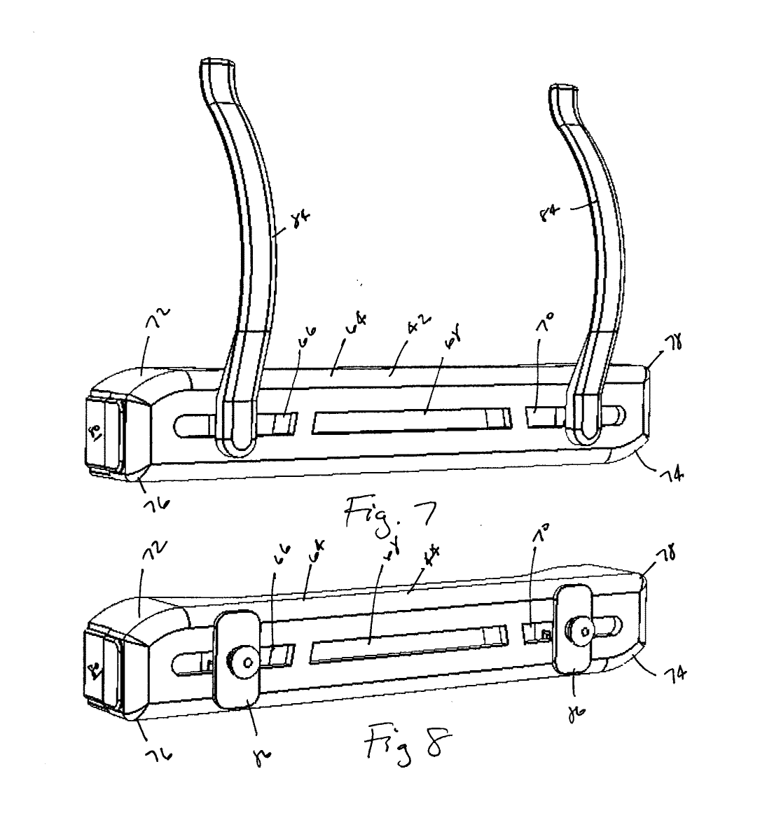

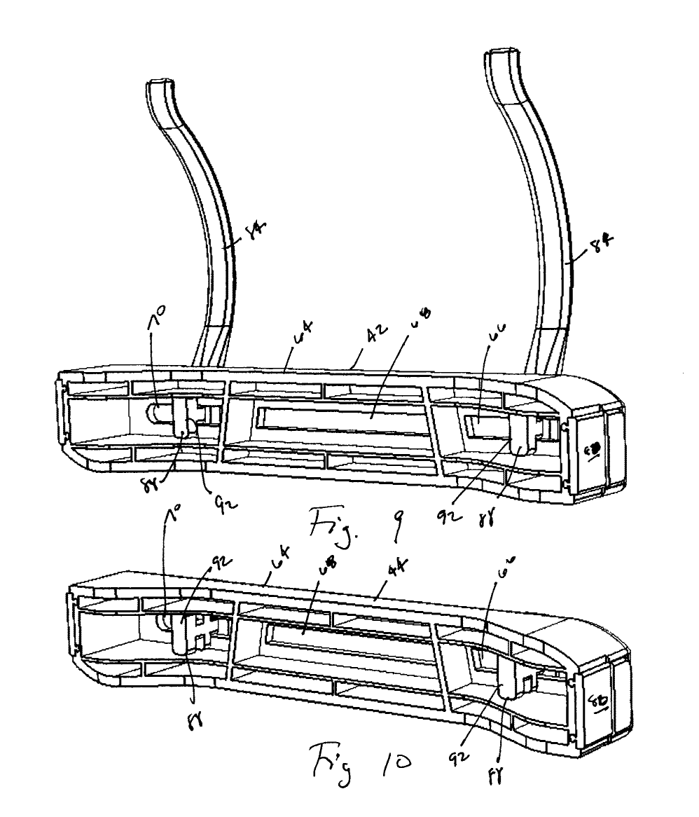

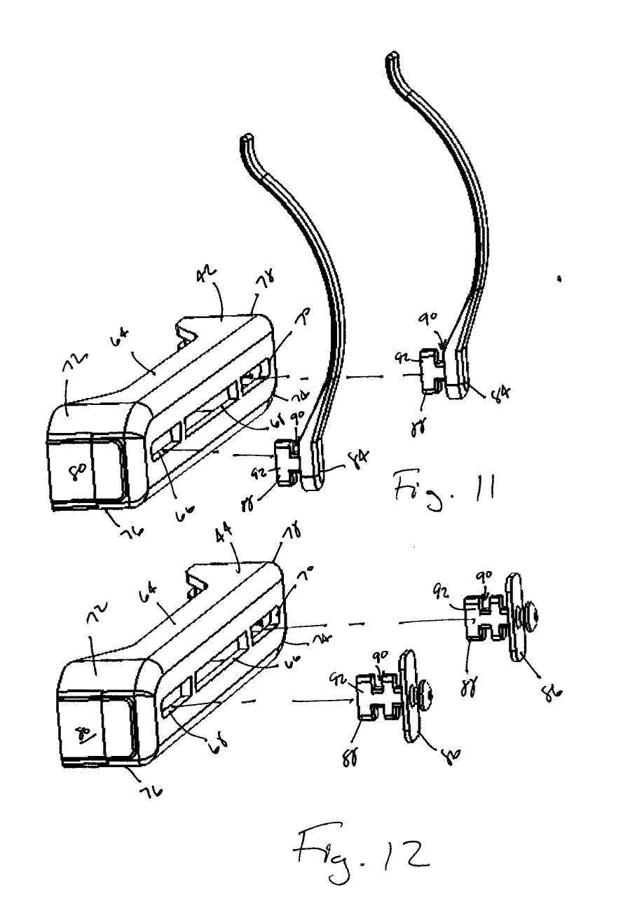

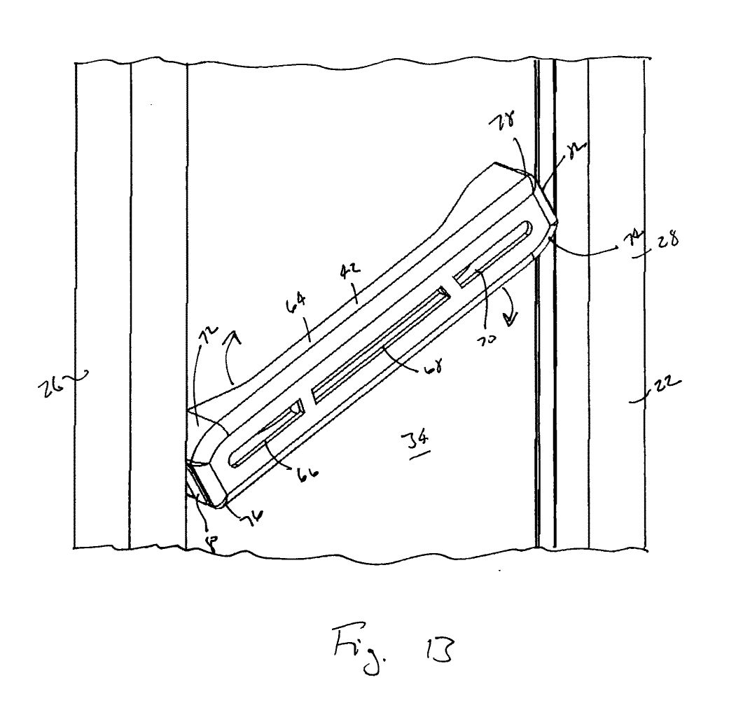

In FIGS. 1-15 there is depicted a column display mount 20 according to an embodiment of the invention. Column display mount 20 generally includes column assembly 22 and tilt head assembly 24. Tilt-head assembly 24 may be similar in function to that disclosed in U.S. Pat. No. 7,152,836, hereby fully incorporated herein by reference.

As depicted in FIG. 1, column display mount 20 can be attached to an article of furniture such as shelf unit 21. It will be appreciated that column display mount 20 may be attached to any other type of furniture piece as may be desired. As further depicted in FIG. 1, a flat panel electronic display 23 (depicted in phantom) such as a monitor or television may then be attached to tilt-head assembly 24 to mount electronic display 23 to the article of furniture.

Column assembly 22 generally includes a pair of spaced-apart square tube members 26, 28, connected with square tube cross-members 30, 32, front panel 34, tilt-head coupler 36, furniture connectors 38, 40, and removable accessory attachment brackets 42, 44. Tilt-head coupler 36 generally includes tilt-head interface bracket 46 which is pivotally coupled with support interface bracket 48 at pivot bolt 50. Tilt-head interface bracket 46 receives tilt-head assembly 24 on mounting surface 52, while support interface bracket is attached to members 30, 32, with fasteners 54. Tilt-head interface bracket 46 is horizontally pivotable about bolt 50 to enable pivoting of flat panel display 56 from side-to-side.

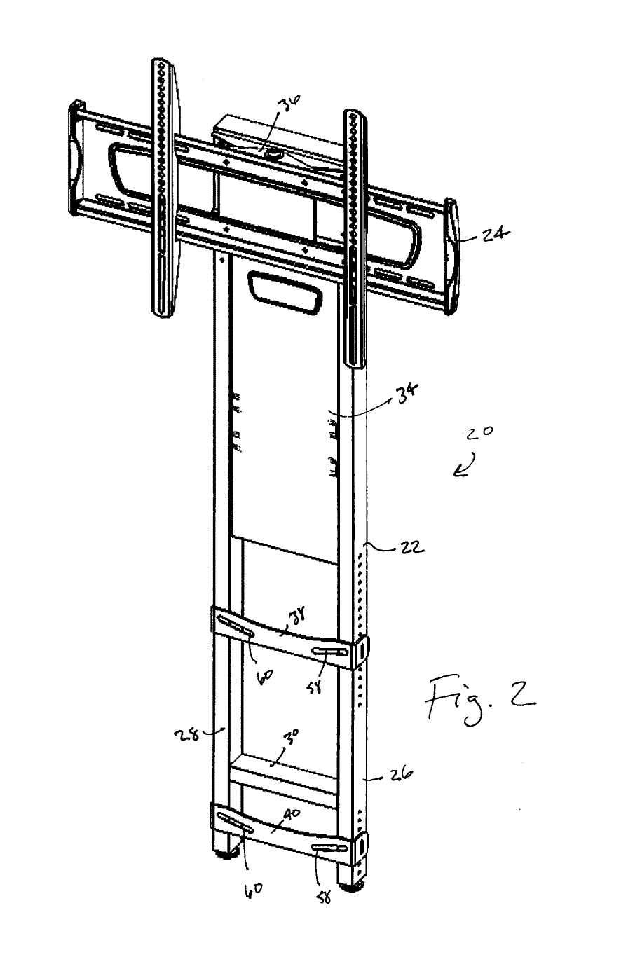

Furniture connectors 38, 40, attach to tube members 26, 29, respectively, as depicted in FIGS. 2, 3, and 5, and each define a pair of angled elongate slots 58, 60. Column display mount 20 is coupled to furniture piece 62 with fasteners (not depicted), extending through slots 58, 60. The geometry of furniture connectors 38, 40, provides certain discrete advantages. First, slots 58, 60, enable attachment of column display mount 20 to an extremely broad range of A/V furniture of different models, makes, and styles. The angled slots 58, 60, automatically ensure column display mount 20 is centered behind the furniture piece and not slightly off to one side or the other. In addition, furniture connectors 38, 40, attach to the outside of members 26, 28, instead of the front. This enables column display mount 20 to be compatible with a significant range of furniture of different heights without compromising aesthetics. When connecting to shorter pieces of furniture, the upper holes for attaching the pillar may become exposed above the top of the furniture piece but do not become visible from the front.

Removable accessory attachment brackets 42, 44, generally each include body portion 64, which may be molded from plastic in a single piece, defining horizontal slots 66, 68, 70. Opposing corners 72, 74, of body portion 64 may be slightly rounded as depicted, while corners 76, 78, are more squared.

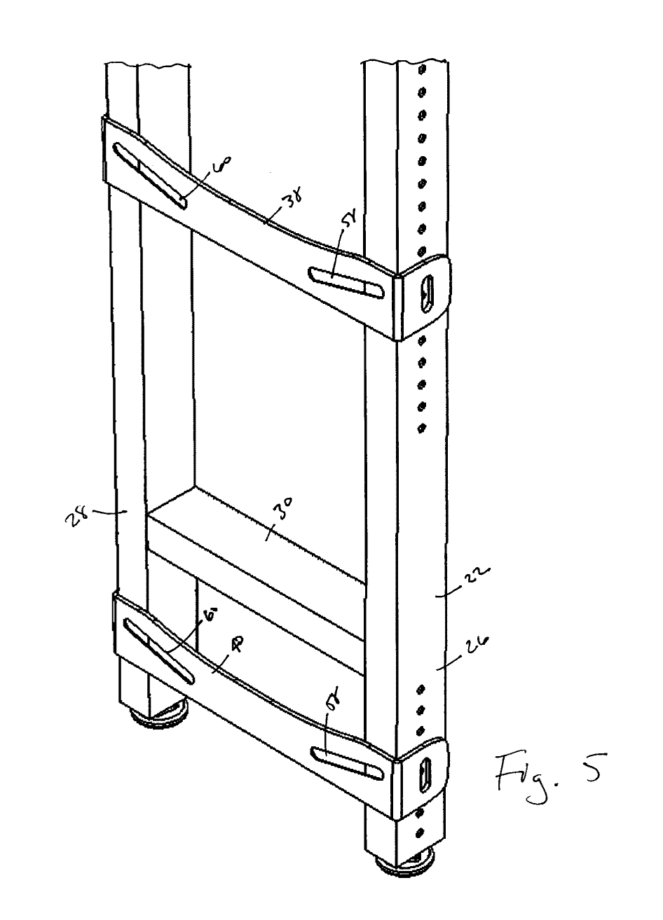

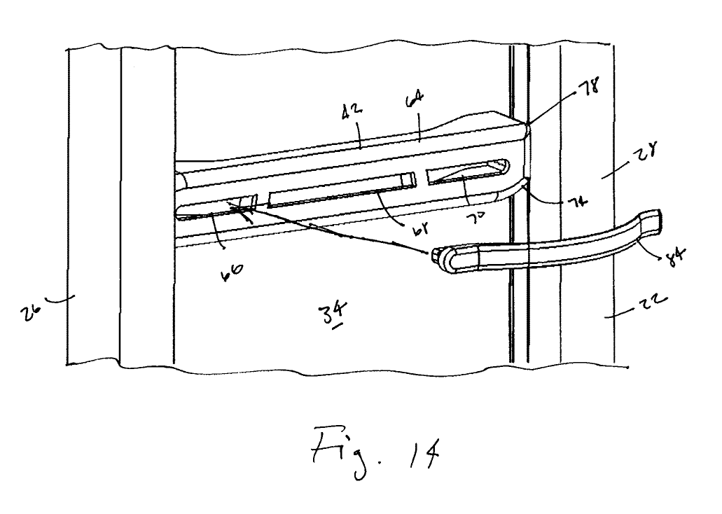

As depicted in FIG. 13, each removable accessory attachment bracket 42, 44, is installed between members 26, 28, by inserting the bracket at a slight angle as depicted and rotating in the direction of the arrows. Rounded corners 72, 74, ride against the inwardly facing surfaces of members 26, 28, enabling rotation of bracket 42, 44, until side surfaces 80, 82, are abutted against the he inwardly facing surfaces of members 26, 28, and bracket 42, 44, is firmly wedged between members 26, 28, as depicted in FIG. 6. Removal is the reverse of installation.

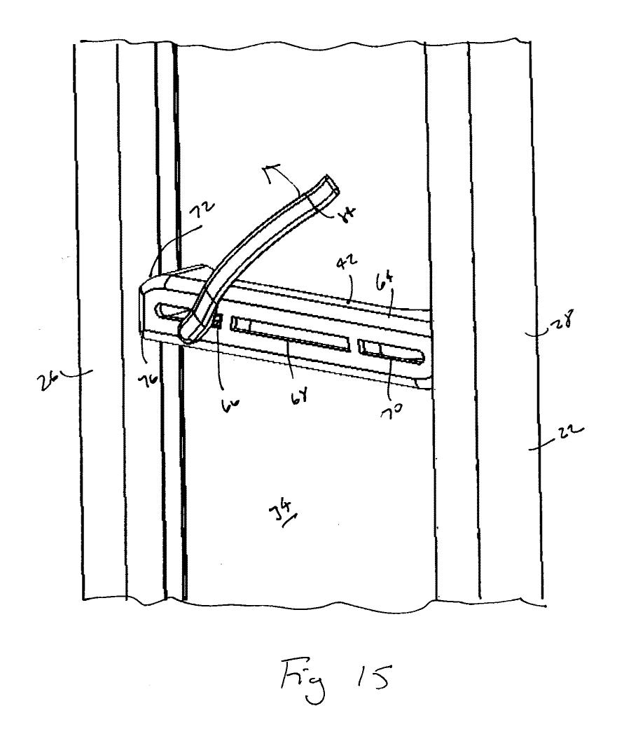

With the bracket 42, 44, wedged in place, attachment members such as hooks 84, or screw attachment points 86, may be attached in slots 66, 68, 70. Each hook 84 and point 86 has attachment portion 88 defining narrowed portion 90. To attach hooks 84 and points 86, the hook or point is rotated 90 degrees as depicted in FIG. 14 so as to enable end portion 92 of each attachment portion to pass through slot 66, 68, 70. The hook 84 or point 86 is then rotated as depicted in FIG. 15 to lodge end portion 92 behind the front face of body portion 64, thereby securing the hook 84 or point 86 in place. Removal is the reverse of installation.

It will be appreciated that in addition to the unitary, single piece construction of the body portion of the depicted accessory attachment bracket 42, 44, other configurations are contemplated which would enable the bracket 42, 44, to be similarly wedged into position between members 26, 28. For example, the body portions of each bracket 42, 44, might be comprised of two or more separate pieces, linearly slidable relative to each other along a longitudinal axis of the bracket 42, 44. The separate parts of the body portion of each bracket 42, 44, could be coupled with a ratchet assembly, enabling free extension to elongate the bracket 42, 44, but preventing shortening of the bracket 42, 44, without manual release of the ratchet mechanism. In this way, the bracket could be inserted between the members 26, 28, and extended to abut the ends of the bracket against the side surfaces of the members 26, 28, to wedge the bracket 42, 44, in place. The separate pieces of the body portion could be arranged in a telescoping or parallel arrangement. These, and other arrangements by which brackets can be wedged in place between members 26, 28, are contemplated and included within the scope of the invention.

The embodiments above are intended to be illustrative and not limiting. Additional embodiments are encompassed within the scope of the claims. Although the present invention has been described with reference to particular embodiments, those skilled in the art will recognize that changes may be made in form and detail without departing from the spirit and scope of the invention. For purposes of interpreting the claims for the present invention, it is expressly intended that the provisions of Section 112, sixth paragraph of 35 U.S.C. are not to be invoked unless the specific terms “means for” or “step for” are recited in a claim.

What is claimed is:

1. A mounting device for attaching an electronic display to an article of furniture, the device comprising:
a body portion including a pair of spaced-apart elongate vertical members, the body portion presenting a top end and a bottom end and defining structure proximate the bottom end for attaching the body portion to the article of furniture;
a display mount coupled to the body portion proximate the top end, the display mount adapted to receive the electronic display thereon; and
a selectively removable accessory attachment bracket frictionally engaged between the vertical members of the body portion.

2. The mounting device of claim 1, wherein the display mount includes a tilt-head assembly.

3. The mounting device of claim 1, wherein the structure for attaching the body portion comprises a slot angled with respect to the horizontal.

4. The mounting device of claim 1, wherein each of the vertical members has a square cross-section.

5. The mounting device of claim 1, wherein the accessory attachment bracket comprises an elongate member presenting four corners, two of the corners being rounded.

6. The mounting device of claim 5, wherein the accessory attachment bracket defines structure for receiving an accessory mounting attachment.

7. The mounting device of claim 6, wherein the structure for receiving an accessory mounting attachment comprises a slot.

8. The mounting device of claim 7, further comprising a hook structure received in the slot.

9. An article of furniture comprising:
a shelf structure presenting at least one horizontally oriented shelf surface;
a mounting device for attaching an electronic display to the shelf structure, the device comprising:
a body portion including a pair of spaced-apart elongate vertical members, the body portion presenting a top end and a bottom end and defining a pair of angled slots proximate the bottom end for receiving fasteners to attach the body portion to the shelf structure; and
a display mount coupled to the body portion proximate the top end, the display mount adapted to receive the electronic display thereon.

10. The article of furniture of claim 9, further comprising a selectively removable accessory attachment bracket frictionally engaged between the vertical members of the body portion.

11. The article of furniture of claim 10, wherein the accessory attachment bracket comprises an elongate member presenting four corners, two of the corners being rounded.

12. The article of furniture of claim 11, wherein the accessory attachment bracket defines structure for receiving an accessory mounting attachment.

13. The article of furniture of claim 12, wherein the structure for receiving an accessory mounting attachment comprises a slot.

14. The article of furniture of claim 9, wherein the display mount includes a tilt-head assembly.

15. The article of furniture of claim 9, wherein each of the vertical members has a square cross-section.

16. A mounting device for attaching an electronic display to an article of furniture, the device comprising:
a body portion including a pair of spaced-apart elongate vertical members, the body portion presenting a top end and a bottom end and defining a pair of angled slots proximate the bottom end for attaching the body portion to the article of furniture; and
a display mount coupled to the body portion proximate the top end, the display mount adapted to receive the electronic display thereon.

17. The mounting device of claim 16, further comprising a selectively removable accessory attachment bracket frictionally engaged between the vertical members of the body portion.

18. The mounting device of claim 17, wherein the accessory attachment bracket comprises an elongate member presenting four corners, two of the corners being rounded.

19. The mounting device of claim 16, wherein the display mount includes a tilt-head assembly.

20. The mounting device of claim 16, wherein each of the vertical members has a square cross-section.
